(19) United States
(12) Patent Application Publication
(10) Pub. No.: US 2015/0027526 A1
(43) Pub. Date: Jan. 29, 2015

(54) SOLAR CELL MODULE AND METHOD OF FABRICATING THE SAME

(71) Applicant: LG INNOTEK CO., LTD., Seoul (KR)

(72) Inventor: Suk Jae Jee, Seoul (KR)

(73) Assignee: LG INNOTEK CO., LTD., Seoul (KR)

(21) Appl. No.: 14/361,608

(22) PCT Filed: Nov. 26, 2012
(86) PCT No.: PCT/KR2012/010050

§ 371 Date: May 29, 2014

(30) Foreign Application Priority Data
Nov. 29, 2011 (KR) 10-2011-0126246

(51) Int. Cl. H01L 31/0216; H01L 31/0224

(52) U.S. Cl. CPC H01L 31/02167; H01L 31/022466
USPC 136/256; 136/252

(57) ABSTRACT

Disclosed are a solar cell module and a method of fabricating the same. The solar cell module includes a back electrode layer on a support substrate; a light absorbing layer on the back electrode layer; a first buffer layer on the light absorbing layer; a second buffer layer on the buffer layer; and a front electrode layer on the second buffer layer.

### TECHNICAL FIELD

The embodiment relates to a solar cell module and a method of fabricating the same.

### BACKGROUND ART

Solar cells may be defined as devices to convert light energy into electrical energy by using a photovoltaic effect of generating electrons when light is incident onto a P-N junction diode. The solar cell may be classified into a silicon solar cell, a compound semiconductor solar cell mainly including a group I-III-VI compound or a group III-V compound, a dye-sensitized solar cell, and an organic solar cell according to materials constituting the junction diode.

A solar cell made from CIGS (CuInGaSe), which is one of group I-III-VI Chal-copyrite-based compound semiconductors, represents superior light absorption, higher photoelectric conversion efficiency with a thin thickness, and superior electro-optic stability, so the CIGS solar cell is spotlighted as a substitute for a conventional silicon solar cell.

In general, a CIGS solar cell can be prepared by sequentially forming a back electrode layer, a light absorbing layer and a front electrode layer on a substrate including sodium. Among the above layers, the buffer layer is disposed between the light absorbing layer and the front electrode layer, which represent great difference in lattice coefficient and energy bandgap, to form a desired junction. According to the related art, cadmium sulfide (CdS) is mainly used for the buffer layer. However, there are disadvantages that cadmium (Cd) has toxicity and the buffer layer is manufactured through a wet process, such as chemical bath deposition (CBD).

In order to solve the above problems, recently, a Cd-free solar cell using zinc sulfide (ZnS) having a bandgap higher than that of the CdS as a material for the buffer layer is spotlighted. Since a ZnS buffer layer used in the Cd-free solar cell is weak against external impact, a metal organic chemical vapor deposition (MOCVD) process is performed instead of a sputtering process when a front electrode layer is formed on the buffer layer. In general, it is difficult to control the deposition uniformity in the MOCVD process when comparing with the sputtering process.

### DISCLOSURE OF INVENTION

### Technical Problem

The embodiment provides a solar cell module including a buffer layer having the high resistance against external damage and providing the improved photoelectric conversion efficiency and a method of fabricating the same.

### Solution to Problem

According to the first embodiment, there is provided a solar cell module including a back electrode layer on a support substrate; a light absorbing layer on the back electrode layer; a first buffer layer on the light absorbing layer; a second buffer layer on the buffer layer and expressed as following chemical formula 2; and a front electrode layer on the second buffer layer.

According to the second embodiment, there is provided a solar cell module including a front electrode layer disposed on a support substrate and formed with a first through hole for exposing a portion of the support substrate; a light absorbing layer formed on the first through hole and the back electrode layer; a first buffer layer formed on the light absorbing layer and expressed as chemical formula 1; a second through hole formed through the light absorbing layer and the first buffer layer to expose a portion of the back electrode layer; a second buffer layer formed on the first buffer layer and expressed as chemical formula 2; and a front electrode layer formed on the second buffer layer and gap-filled in the second through hole.

According to the embodiment, there is provided a method of fabricating a solar cell module, the method including forming a back electrode layer on a support substrate; forming a light absorbing layer on the back electrode layer; forming a first buffer layer on the light absorbing layer; forming a second buffer layer expressed as following chemical formula 2 on the first buffer layer; and forming a front electrode layer on the second buffer layer,

[Chemical Formula 1]

ZnO_{1-X}S_{X} (0<X≦0.4 or 0.8≦X≦0.9)

[Chemical Formula 2]

Zn_{1-Y}Mg_{Y}O (0.15≦Y≦0.25).

### Advantageous Effects of Invention

According to the solar cell module of the embodiment, the second buffer layer is formed between the first buffer layer and the front electrode layer. The second buffer layer can reduce the damage and pin holes, which may be generated in the first buffer layer in the process of forming the front electrode layer, and can prevent the shunt to increase the open-circuit voltage Voc.

In addition, the bandgap energy Eg of the second buffer layer has the intermediate value between the bandgap energy of the first buffer layer and the bandgap energy of the front electrode layer. That is, according to the embodiment, the bandgap of the second buffer layer can be aligned with the bandgaps of adjacent layers, so the recombination of the electron-hole can be minimized and the photoelectric conversion efficiency can be improved.

### BRIEF DESCRIPTION OF DRAWINGS

FIG. 1 is a sectional view showing a solar cell module according to the first embodiment;

FIG. 2 is a sectional view showing a solar cell module according to the second embodiment; and

FIGS. 3 to 6 are sectional views showing a method of fabricating a solar cell module according to the second embodiment.

### MODE FOR THE INVENTION

In the description of the embodiments, it will be understood that, when a substrate, a layer, a film, or an electrode is referred to as being “on” or “under” another substrate, another layer, another film, or another electrode, it can be “directly” or “indirectly” on the other substrate, the other layer, the other film, or the other electrode, or one or more intervening layers may also be present. Such a position of each component has been described with reference to the drawings. The thickness and size of each component shown in the drawings may be exaggerated, omitted or schematically drawn for the purpose of convenience or clarity. In addition, the size of elements does not utterly reflect an actual size.

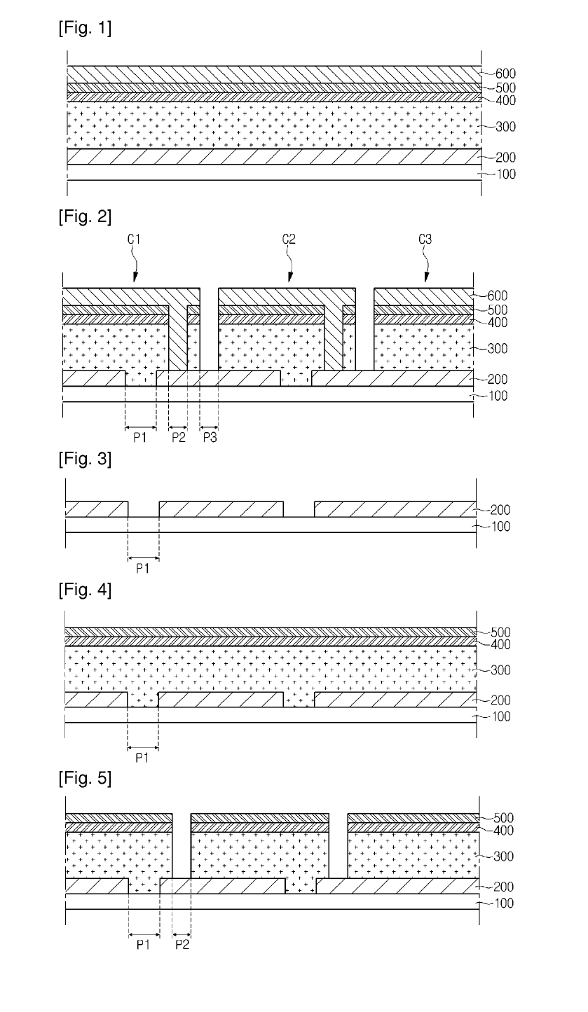

FIG. 1 is a sectional view showing a solar cell module according to the first embodiment.

Referring to FIG. 1, a solar cell according to the first embodiment includes a support substrate 100, a back electrode layer 200, a light absorbing layer 300, a first buffer layer 400, a second buffer layer 500, and a front electrode layer 600.

The support substrate 100 has a plate shape and supports the back electrode layer 200, the light absorbing layer 300, the first buffer layer 400, the second buffer layer 500, and the front electrode layer 600.

The support substrate 100 may be an insulator. For example, the support substrate 100 may be a glass substrate, a plastic substrate or a metal substrate. In detail, the support substrate 100 may be a soda lime glass substrate. The support substrate 100 may be transparent. The support substrate 100 may be rigid or flexible.

The back electrode layer 200 is a conductive layer. The back electrode layer 200 may include at least one of molybdenum (Mo), gold (Au), aluminum (Al), chrome (Cr), tungsten (W), and copper (Cu). Among the above materials, the Mo has a thermal expansion coefficient similar to that of the support substrate 100, so the Mo may improve the adhesive property and prevent the back electrode layer 200 from being delaminated from the substrate 100. That is, the characteristics required to the back electrode layer 200 may be satisfied overall by the Mo.

The light absorbing layer 300 is provided on the back electrode layer 200. The light absorbing layer 300 includes a group I-III-VI compound. For example, the light absorbing layer 300 may have the CIGSS (Cu(IN,Ga)(Se,S)₂) crystal structure, the CISS (Cu(IN)(Se,S)₂) crystal structure or the CGSS (Cu(Ga)(Se,S)₂) crystal structure. In addition, the light absorbing layer 300 may have an energy bandgap in the range of about 1 eV to about 1.8 eV.

The first buffer layer 400 is disposed on the light absorbing layer 300. In the solar cell according to the embodiment, the PN junction is formed between the light absorbing layer 300 including CIGS or CIGSS compound serving as a P type semiconductor and the front electrode layer 600 serving as an N type semiconductor. However, since there is great difference in lattice coefficient and bandgap energy between the above light absorbing layer 300 and the front electrode layer 600, a buffer layer having the bandgap between the bandgaps of the two layers is necessary to form the desired junction. Meanwhile, the first buffer layer 400 may be expressed as following chemical formula 1. In addition, the first buffer layer 400 may have a thickness in the range of about 10 nm to 30 nm, but the embodiment is not limited thereto.

[Chemical Formula 1]

ZnO_{1-X}S_{X} (0<X≦0.4 or 0.8≦X≦0.9)

The second buffer layer 500 is disposed on the first buffer layer 400. As described above, a ZnS-based buffer layer is weak against external impact. In order to solve this problem, according to the solar cell module of the embodiment, the second buffer layer 500 having the high resistant against the external impact is formed on the first buffer layer 400 to protect the first buffer layer 400 from the external impact. In addition, the front electrode layer 600 can be formed on the first buffer layer 400 through the sputtering process. Thus, the deposition uniformity of the front electrode layer 600 can be improved due to the second buffer layer 500.

Meanwhile, the second buffer layer 500 may be expressed as following chemical formula 2. In addition, the second buffer layer 500 may have a thickness in the range of about 10 nm to 30 nm, but the embodiment is not limited thereto.

[Chemical Formula 2]

Zn_{1-Y}Mg_{Y}O (0.15≦Y≦0.25)

The front electrode layer 600 is formed on the second buffer layer 500. The front electrode layer 600 is a transparent conductive layer. For instance, the front electrode layer 600 may include B doped zinc oxide (BZO, ZnO:B), Al doped zinc oxide (AZO) or Ga doped zinc oxide (GZO). In detail, the B doped zinc oxide (BZO, ZnO:B) is used for the front electrode layer 600 by taking the bandgap and contact with respect to the first buffer layer 400 into consideration.

In the solar cell module according to the embodiment, the light absorbing layer 300, the first buffer layer 400, the second buffer layer 500 and the front electrode layer 600 may have the sequentially aligned bandgap energy (Eg). Thus, the solar cell module according to the embodiment can minimize the recombination of the electron-hole and can improve the photoelectric conversion efficiency.

According to one embodiment, when the light absorbing layer 300 has first bandgap energy, the first buffer layer 400 has second bandgap energy and the second buffer layer 500 has third bandgap energy, the second bandgap energy is higher than the first bandgap energy and lower than the third bandgap energy. For instance, the first bandgap energy is in the range of about 1.00 eV to about 1.80 eV, the second bandgap energy is in the range of about 2.50 eV to about 3.20 eV, and the third bandgap energy is in the range of about 3.40 eV to about 3.80 eV, but the embodiment is not limited thereto.

The content X of sulfur (S) in the first buffer layer 400 expressed as chemical formula 1 may be adjusted to allow the first buffer layer 400 to have the above bandgap energy (Eg) in the range of about 2.50 eV to about 3.20 eV. For instance, the content X of sulfur (S) may be adjusted from about 0 to about 0.4 or from about 0.8 to about 0.9. If the content X of sulfur (S) is increased from about 0 to about 0.4, the bandgap energy of the first buffer layer 400 is reduced from about 3.20 eV to about 2.50 eV. In addition, if the content X of sulfur (S) is increased from about 0.8 to about 0.9, the bandgap energy of the first buffer layer 400 is increased from about 2.50 eV to about 3.20 eV.

[Chemical Formula 1]

ZnO_{1-X}S_{X}

The content Y of magnesium (Mg) in the second buffer layer 500 expressed as chemical formula 1 may be adjusted to allow the second buffer layer 500 to have the above bandgap energy (Eg) in the range of about 3.40 eV to about 3.80 eV. For instance, the content Y of magnesium (Mg) may be adjusted from about 0.15 to about 0.25. If the content Y of magnesium (Mg) is increased from about 0.15 to about 0.25, the bandgap energy of the second buffer layer 500 is increased from about 3.40 eV to about 3.80 eV.

[Chemical Formula 2]

Zn_{1-Y}Mg_{Y}O

In this manner, the solar cell module according to the embodiment provides the buffer layers 400 and 500 having the sequential bandgap energy, so the recombination of the electron-hole can be minimized and the photoelectric conversion efficiency can be improved.

FIG. 2 is a sectional view showing a solar cell module according to the second embodiment and FIGS. 3 to 6 are sectional views showing a method of fabricating a solar cell module according to the embodiment.

Referring to FIG. 2, the solar cell module according to the second embodiment incudes a front electrode layer 200 disposed on a support substrate 100 and formed with a first through hole P1 for exposing a portion of the support substrate 100; a light absorbing layer 300 formed on the first through hole P1 and the back electrode layer 200; a first buffer layer 400 formed on the light absorbing layer 300 and expressed as chemical formula 1; a second through hole P2 formed through the light absorbing layer 300 and the first buffer layer 400 to expose a portion of the back electrode layer 200; a second buffer layer 500 formed on the first buffer layer 400 and expressed as chemical formula 2; and a front electrode layer 600 formed on the second buffer layer 500 and gap-filled in the second through hole P2.

Hereinafter, the method of fabricating the solar cell module according to the second embodiment will be described with reference to FIGS. 3 to 6. The description about the solar cell according to the first embodiment will be incorporated herein by reference.

Referring to FIG. 3, the back electrode layer 200 is formed on the support substrate 100 and the back electrode layer 200 is patterned to form the first through hole P1. The first through hole P1 is an open region to expose a top surface of the support substrate 100. The first through hole P1 may have a width in the range of about 50 μm to 100 μm.

Thus, a plurality of back electrode layers are formed on the support substrate 100. The back electrode layer 200 may be patterned by a laser, but the embodiment is not limited thereto.

Referring to FIG. 4, the light absorbing layer 300, the first buffer layer 400 and the second buffer layer 500 are sequentially formed on the back electrode layer 200.

The light absorbing layer 300 may be formed through the sputtering process or the evaporation process.

For instance, the light absorbing layer 300 may be formed through various schemes such as a scheme of forming a Cu(In,Ga)Se₂ (CIGS) based light absorbing layer 300 by simultaneously or separately evaporating Cu, In, Ga, and Se and a scheme of performing a selenization process after a metal precursor layer has been formed.

Regarding the details of the selenization process after the formation of the metal precursor layer, the metal precursor layer is formed on the back electrode layer 200 through a sputtering process employing a Cu target, an In target and a Ga target. Then, the metal precursor layer is subject to the selenization process so that the Cu(In, Ga)Se₂ (CIGS) based light absorbing layer 300 is formed.

In addition, the sputtering process employing the Cu target, the In target, and the Ga target and the selenization process may be simultaneously performed.

Further, a CIS or a CIG based light absorbing layer 300 may be formed through the sputtering process employing only Cu and In targets or only Cu and Ga targets and the selenization process.

Then, the first buffer layer 400 is formed on the light absorbing layer 300. As described above, the first buffer layer 400 can be expressed as chemical formula 1 (ZnO_{1-X}S_{X} (0<X≦0.4 or 0.8≦X≦0.9)). For instance, the first buffer layer 400 can be formed through atomic layer deposition (ALD), metal-organic chemical vapor deposition (MOCVD) or chemical bath deposition (CBD).

After that, the second buffer layer 500 is formed on the first buffer layer 400. As described above, the second buffer layer 500 can be expressed as chemical formula 2 (Zn_{1-Y}Mg_{Y}O (0.15≦Y≦0.25)). For instance, the second buffer layer 500 can be formed through the sputtering, MOCVD or CBD.

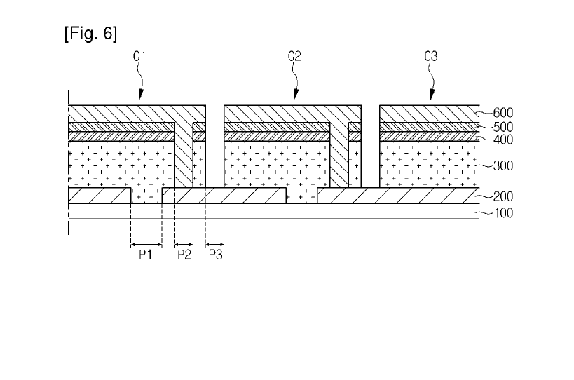

Referring to FIG. 5, the light absorbing layer 300, the first buffer layer 400 and the second buffer layer 500 are partially removed to form the second through hole P2. A plurality of light absorbing portions are defined by the second through hole P2. That is, the light absorbing layer 300 is divided into the light absorbing portions by the second through hole P2.

The second through hole P2 is adjacent to the first through hole P1. That is, when viewed from the top, a portion of the second through hole P2 is formed next to the first through hole P1. The second through hole P2 may have a width in the range of about 40 μm to about 150 μm, but the embodiment is not limited thereto.

Referring to FIG. 6, a transparent conductive material is deposited on the second buffer layer 500 to form the front electrode layer 600. When depositing the front electrode layer 600, the transparent conductive material is gap-filled in the second through hole P2. The transparent conductive material gap-filled in the second through hole P2 may serve as a connection wire to electrically connect the front electrode layer 600 with the back electrode layer 200.

The front electrode layer 600 may include B doped zinc oxide (BZO), Al doped zinc oxide (AZO) or Ga doped zinc oxide (GZO). In detail, the B doped zinc oxide (BZO) is used for the front electrode layer 600 by taking the bandgap and contact with respect to the first buffer layer 400 into consideration.

The front electrode layer 600 may be deposited through the sputtering or MOCVD. In detail, the front electrode layer 600 may be deposited through the sputtering. According to the method of fabricating the solar cell module of the embodiment, the second buffer layer 500 doped with Mg having high resistance against external impact is formed on the first buffer layer 400, which is weak against the external impact, so the front electrode layer 600 can be formed through the sputtering process. Thus, the front electrode layer 600 can be uniformly deposited and the deposition rate can be constantly maintained even when the front electrode layer 600 is deposited on a large-size substrate.

Then, the third through hole P3 is formed to divide the front electrode layer 600. The third through hole P3 is formed through the front electrode layer 600, the second buffer layer 500, the first buffer layer 400 and the light absorbing layer 300 to expose a portion of the back electrode layer 200. That is, the solar cell module may be divided into a plurality of solar cells C1, C2 . . . and Cn by the third through hole P3. The third through hole P3 can be formed through the mechanical scheme and may have a width in the range of about 80 μm to about 200 μm, but the embodiment is not limited thereto.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A solar cell module comprising:
a back electrode layer on a support substrate;
a light absorbing layer on the back electrode layer;
a first buffer layer on the light absorbing layer;
a second buffer layer on the first buffer layer and expressed as following chemical formula 2; and
a front electrode layer on the second buffer layer,
[Chemical Formula 2]
Zn_{1-Y}Mg_{Y}O (0.15≦Y≦0.25).

2. The solar cell module of claim 1, wherein the first buffer layer is expressed as following chemical formula 1,
[Chemical Formula 1]
ZnO_{1-X}S_{X} (0<X≦0.4 or 0.8≦X≦0.9).

3. The solar cell module of claim 1, wherein the front electrode layer includes BZO (ZnO:B).

4. The solar cell module of claim 1, wherein the first buffer layer has a thickness in a range of 10 nm to 30 nm and the second buffer layer has a thickness in a range of 10 nm to 30 nm.

5. The solar cell module of claim 1, wherein, when the light absorbing layer has a first bandgap energy, the first buffer layer has a second bandgap energy, and the second buffer layer has a third bandgap energy, the second bandgap energy is higher than the first bandgap energy and lower than the third bandgap energy.

6. The solar cell module of claim 5, wherein the first bandgap energy is in a range of 1.00 eV to 1.80 eV, the second bandgap energy is in a range of 2.50 eV to 3.20 eV, and the third bandgap energy is in a range of 3.40 eV to 3.80 eV.

7. A solar cell module comprising:
a back electrode layer disposed on a support substrate and formed with a first through hole for exposing a portion of the support substrate;
a light absorbing layer formed on the first through hole and the back electrode layer;
a first buffer layer formed on the light absorbing layer and expressed as following chemical formula 1;
a second through hole formed through the light absorbing layer and the first buffer layer to expose a portion of the back electrode layer;
a second buffer layer formed on the first buffer layer and expressed as following chemical formula 2; and
a front electrode layer formed on the second buffer layer and gap-filled in the second through hole,
[Chemical Formula 1]
ZnO_{1-X}S_{X} (0<X≦0.4 or 0.8≦X≦0.9)
[Chemical Formula 2]
Zn_{1-Y}Mg_{Y}O (0.15≦Y≦0.25).

8. The solar cell module of claim 7, wherein the front electrode layer includes BZO (ZnO:B).

9. The solar cell module of claim 7, wherein the first buffer layer has a thickness in a range of 10 nm to 30 nm and the second buffer layer has a thickness in a range of 10 nm to 30 nm.

10. The solar cell module of claim 7, wherein the light absorbing layer has a bandgap energy in a range of 1.00 eV to 1.80 eV, the first buffer layer has a bandgap energy in a range of 2.50 eV to 3.20 eV, and the second buffer layer has a bandgap energy in a range of 3.40 eV to 3.80 eV.

11-15. (canceled)

16. The solar cell module of claim 5, wherein the bandgap energy of the first buffer expressed as chemical formula 1 is adjusted by a content X of sulfur (S).

17. The solar cell module of claim 16, wherein the adjusted bandgap of the first buffer is in inverse proportion to the content X of sulfur(S).

18. The solar cell module of claim 5, wherein the bandgap energy of the second buffer expressed as chemical formula 2 is adjusted by a content Y of magnesium (MG).

19. The solar cell module of claim 16, wherein the adjusted bandgap of the second buffer is in proportion to the content Y of magnesium(MG).
